(19) United States
(12) Patent Application Publication
(10) Pub. No.: US 2021/0408472 A1
(43) Pub. Date: Dec. 30, 2021

(54) DISPLAY SUBSTRATE, DISPLAY APPARATUS, AND METHOD OF FABRICATING DISPLAY SUBSTRATE

(71) Applicant: BOE Technology Group Co., Ltd., Beijing (CN)

(72) Inventors: Ziyu Zhang, Beijing (CN); Song Zhang, Beijing (CN)

(73) Assignee: BOE Technology Group Co., Ltd., Beijing (CN)

(21) Appl. No.: 16/769,373

(22) PCT Filed: May 31, 2019
(86) PCT No.: PCT/CN2019/089421

§ 371 Date: Jun. 3, 2020

(51) Int. Cl. H01L 51/52; H01L 51/56; H01L 27/32

(52) U.S. Cl. CPC H01L 51/5253; H01L 27/3258; H01L 51/56

(57) ABSTRACT

A display substrate having a display area and a peripheral area is provided. The display substrate includes a base substrate; a plurality of light emitting elements on the base substrate and in the display area; an encapsulating layer on a side of the plurality of light emitting elements distal to the base substrate to encapsulate the plurality of light emitting elements; an insulating layer between the encapsulating layer and the base substrate; a first barrier wall in the peripheral area and on a side of the insulating layer away from the base substrate, the first barrier wall forming a first enclosure substantially surrounding a first area; and a crack prevention layer in an angled space between a lateral side of the first barrier wall and a surface of the insulating layer.

### TECHNICAL FIELD

The present invention relates to display technology, more particularly, to a display substrate, a display apparatus, and a method of fabricating a display substrate.

### BACKGROUND

Organic light emitting diode (OLED) display apparatuses are self-emissive devices, and do not require backlights. OLED display apparatuses also provide more vivid colors and a larger color gamut as compared to the conventional liquid crystal display (LCD) apparatuses. Further, OLED display apparatuses can be made more flexible, thinner, and lighter than a typical LCD apparatus. An OLED display apparatus typically includes an anode, an organic layer including a light emitting layer, and a cathode. OLEDs can be either a bottom-emission type OLED or a top-emission type OLED.

### SUMMARY

In one aspect, the present invention provides a display substrate having a display area and a peripheral area, comprising a base substrate; a plurality of light emitting elements on the base substrate and in the display area; an encapsulating layer on a side of the plurality of light emitting elements distal to the base substrate to encapsulate the plurality of light emitting elements; an insulating layer between the encapsulating layer and the base substrate; a first barrier wall in the peripheral area and on a side of the insulating layer away from the base substrate, the first barrier wall forming a first enclosure substantially surrounding a first area; and a crack prevention layer in an angled space between a lateral side of the first barrier wall and a surface of the insulating layer.

Optionally, the first barrier wall comprises a first lower portion in contact with the insulating layer and a first upper portion on a side of the first lower portion away from the insulating layer; an orthographic projection of the first upper portion on the base substrate covers an orthographic projection of the first lower portion on the base substrate; a first lateral side of the first lower portion forms a first angled space with a surface of the insulating layer; a second lateral side of the first lower portion forms a second angled space with the surface of the insulating layer; and the crack prevention layer comprises a first crack prevention sub-layer in the first angled space and a second crack prevention sub-layer in the second angled space.

Optionally, the first crack prevention sub-layer covers a first lateral side of the first lower portion; and the second crack prevention sub-layer covers the second lateral side of the first lower portion.

Optionally, a side of the first upper portion away from the base substrate is wider than a side of the first upper portion closer to the base substrate; and a side of the first lower portion away from the base substrate is wider than a side of the first lower portion closer to the base substrate.

Optionally, a cross-section of the first barrier wall along a plane perpendicular to the insulating layer along a direction from the first lateral side to the second lateral side has a substantially inverted trapezoidal shape.

Optionally, the first lower portion, the first crack prevention sub-layer, and the second crack prevention sub-layer together forms a structure having a side away from the base substrate narrower than a side closer to the base substrate.

Optionally, a height of the first crack prevention sub-layer relative to the surface of the insulating layer is no more than half of a height of the first barrier wall relative to the surface of the insulating layer; and a height of the second crack prevention sub-layer relative to the surface of the insulating layer is no more than half of a height of the first barrier wall relative to the surface of the insulating layer.

Optionally, the first barrier wall comprises a negative photoresist material; and the crack prevention layer comprises a positive photoresist material.

Optionally, the display substrate further comprises an inorganic blocking layer covering the first barrier wall and the crack prevention layer; the inorganic blocking layer is limited in the peripheral area; and the inorganic blocking layer is in direct contact with the first barrier wall, the crack prevention layer, and the insulating layer.

Optionally, the inorganic blocking layer completely covers, without cracks, lateral sides of a structure formed by the first barrier wall and the crack prevention layer together.

Optionally, the display substrate further comprises one or a combination of an organic material layer and a cathode layer on a side of the inorganic blocking layer away from the base substrate, isolated into discontinued portions by lateral sides of the first barrier wall.

Optionally, at least one inorganic sub-layer of the encapsulating layer extends from the display area into the peripheral area; and the at least one inorganic sub-layer of the encapsulating layer is on a side of the inorganic blocking layer away from the base substrate.

Optionally, the at least one inorganic sub-layer of the encapsulating layer completely covers, without cracks, a portion of the inorganic blocking layer covering the lateral sides of the structure formed by the first barrier wall and the crack prevention layer together.

Optionally, the display substrate further comprises a second barrier wall in the peripheral area and on a side of the insulating layer away from the base substrate, the second barrier wall forming a second enclosure substantially surrounding a second area.

Optionally, the first enclosure substantially surrounds a window region of the display substrate; and the display substrate has an aperture extending through the window region for installing an accessory therein.

In another aspect, the present invention provides a display apparatus, comprising the display substrate described herein or fabricated by a method described herein, and one or more integrated circuits connected to the display substrate.

In another aspect, the present invention provides a method of fabricating a display substrate having a display area and a peripheral area, comprising forming a plurality of light emitting elements on a base substrate and in the display area; forming an encapsulating layer on a side of the plurality of light emitting elements distal to the base substrate to encapsulate the plurality of light emitting elements; forming an insulating layer on the base substrate, wherein the insulating layer is formed between the encapsulating layer and the base substrate; forming a first barrier wall in the peripheral area and on a side of the insulating layer away from the base substrate, the first barrier wall forming a first enclosure substantially surrounding a first area; and forming a crack prevention layer in an angled space between a lateral side of the first barrier wall and a surface of the insulating layer.

Optionally, forming the first barrier wall comprises forming a negative photoresist material layer in the peripheral area and on a side of the insulating layer away from the base substrate; and patterning the negative photoresist material layer to form the first barrier wall; wherein the first barrier wall is formed so that a side of the first barrier wall away from the base substrate is wider than a side of the first barrier wall closer to the base substrate.

Optionally, forming the crack prevention layer comprises forming a positive photoresist material layer on a side of the first barrier wall away from the base substrate; and patterning the positive photoresist material layer to form the crack prevention layer; wherein the positive photoresist material layer is removed during the patterning the positive photoresist material layer, except for a portion in the angled space between the lateral side of the first barrier wall and the surface of the insulating layer, thereby forming the crack prevention layer.

Optionally, the method further comprises punching an aperture through the display substrate to form a window region; wherein the window region is substantially surrounded by the first enclosure.

### BRIEF DESCRIPTION OF THE FIGURES

The following drawings are merely examples for illustrative purposes according to various disclosed embodiments and are not intended to limit the scope of the present invention.

FIG. 1 is a cross-sectional view of a portion of a display substrate in some embodiments according to the present disclosure.

FIG. 2A is a plan view of a display substrate in some embodiments according to the present disclosure.

FIG. 2B is a plan view of a display substrate in some embodiments according to the present disclosure.

FIG. 2C is a plan view of a display substrate in some embodiments according to the present disclosure.

FIG. 3A is a schematic diagram illustrating the structure of a first barrier wall in some embodiments according to the present disclosure.

FIG. 3B is a schematic diagram illustrating the structure of a first barrier wall and a crack prevention layer in some embodiments according to the present disclosure.

FIG. 3C is a schematic diagram illustrating the structure of a first barrier wall, a crack prevention layer, and an inorganic blocking layer in some embodiments according to the present disclosure.

FIG. 3D is a schematic diagram illustrating the structure of an organic material layer and a cathode layer on a first barrier wall in some embodiments according to the present disclosure.

FIG. 4A is a schematic diagram illustrating the structure of a second barrier wall in some embodiments according to the present disclosure.

FIG. 4B is a schematic diagram illustrating the structure of a second barrier wall and a crack prevention layer in some embodiments according to the present disclosure.

FIG. 4C is a schematic diagram illustrating the structure of a second barrier wall, a crack prevention layer, and an inorganic blocking layer in some embodiments according to the present disclosure.

FIG. 4D is a schematic diagram illustrating the structure of an organic material layer and a cathode layer on a second barrier wall in some embodiments according to the present disclosure.

FIGS. 5A to SF illustrate a method of fabricating a display substrate in some embodiments according to the present disclosure.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

It is discovered in the present disclosure that a display panel or a display substrate is particularly prone to moist and oxygen permeation in a window region formed to install an accessory such as a camera. The window region is typically formed by punching a hole through the display substrate. Thus, the encapsulating layer may not be able to encapsulate the display substrate once the window region is formed. Particularly, a fabrication process of an organic light emitting diode display substrate often adopts an open mask process to deposit one or more organic material layer and electrode layer, e.g., without any patterning steps. The encapsulating layer in the window region cannot satisfactorily encapsulate these organic material layer and electrode layer, leading to exposure of the display substrate to external oxygen and moist. Further, the process of forming the window region potentially may produce cracks in a boundary adjacent to the window region. The cracks may propagate into the display area of the display substrate, further adversely affect the display components inside the display area.

Accordingly, the present disclosure provides, inter alia, a display substrate, a display apparatus, and a method of fabricating a display substrate that substantially obviate one or more of the problems due to limitations and disadvantages of the related art. In one aspect, the present disclosure provides a display substrate having a display area and a peripheral area. In some embodiments, the display substrate includes a base substrate; a plurality of light emitting elements on the base substrate and in the display area; an encapsulating layer on a side of the plurality of light emitting elements distal to the base substrate to encapsulate the plurality of light emitting elements; an insulating layer on the base substrate; a first barrier wall in the peripheral area and on a side of the insulating layer away from the base substrate, the first barrier wall forming a first enclosure substantially surrounding a first area; and a crack prevention layer in an angled space between a lateral side of the first barrier wall and a surface of the insulating layer.

As used herein, the term “display area” refers to an area of a display substrate (e.g., an opposing substrate or an array substrate) in a display panel where image is actually displayed. Optionally, the display area may include both a subpixel region and an inter-subpixel region. A subpixel region refers to a light emission region of a subpixel, such as a region corresponding to a pixel electrode in a liquid crystal display or a region corresponding to a light emissive layer in an organic light emitting diode display panel. An inter-subpixel region refers to a region between adjacent subpixel regions, such as a region corresponding to a black matrix in a liquid crystal display or a region corresponding a pixel definition layer in an organic light emitting diode display panel. Optionally, the inter-subpixel region is a region between adjacent subpixel regions in a same pixel. Optionally, the inter-subpixel region is a region between two adjacent subpixel regions from two adjacent pixels.

As used herein the term “peripheral area” refers to an area of a display substrate (e.g., an opposing substrate or an array substrate) in a display panel where various circuits and wires are provided to transmit signals to the display substrate. To increase the transparency of the display apparatus, non-transparent or opaque components of the display apparatus (e.g., battery, printed circuit board, metal frame), can be disposed in the peripheral area rather than in the display areas.

As used herein the term “substantially surrounding” refers to surrounding at least 50% (e.g., at least 60%, at least 70%, at least 80%, at least 90%, at least 95%, at least 99%, and 100%) of a perimeter of an area.

Various appropriate light emitting elements may be used in the present display substrate. Examples of appropriate light emitting elements include organic light emitting diodes, quantum dots light emitting diodes, and micro light emitting diodes.

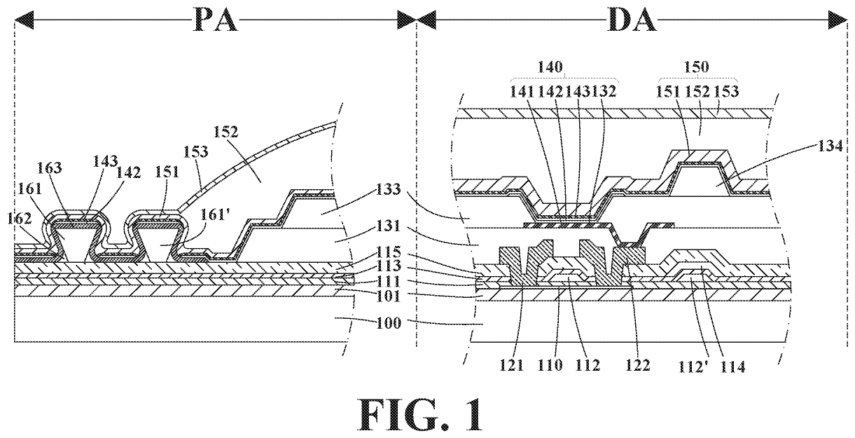

FIG. 1 is a cross-sectional view of a portion of a display substrate in some embodiments according to the present disclosure. Referring to FIG. 1, the display substrate in some embodiments has a display area DA and a peripheral area PA. In some embodiments, the display substrate includes a base substrate 100; a plurality of light emitting elements 140 on the base substrate 100 and in the display area DA; an encapsulating layer 150 on a side of the plurality of light emitting elements 140 distal to the base substrate 100 to encapsulate the plurality of light emitting elements 140; an insulating layer 115 on the base substrate 100; a first barrier wall 161 in the peripheral area PA and on a side of the insulating layer 115 away from the base substrate 100, the first barrier wall 161 forming a first enclosure substantially surrounding a first area; and a crack prevention layer 162 in an angled space between a lateral side of the first barrier wall 161 and a surface of the insulating layer 115.

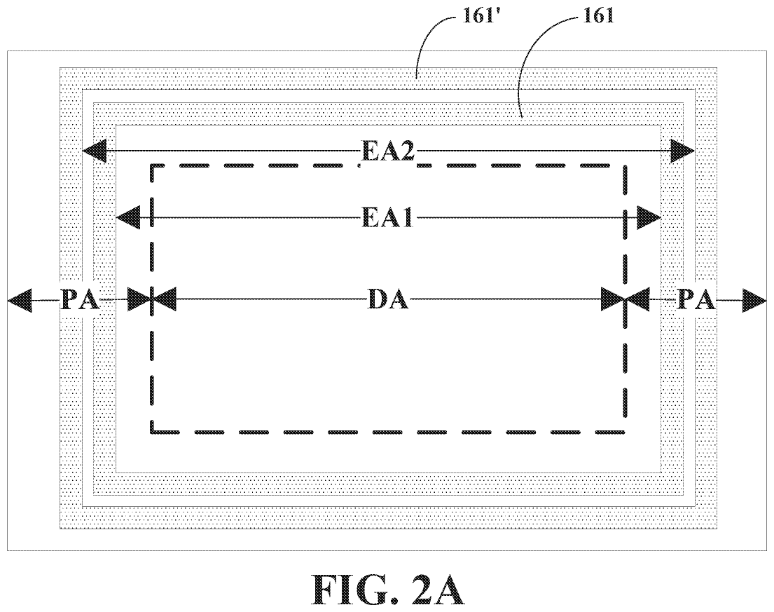

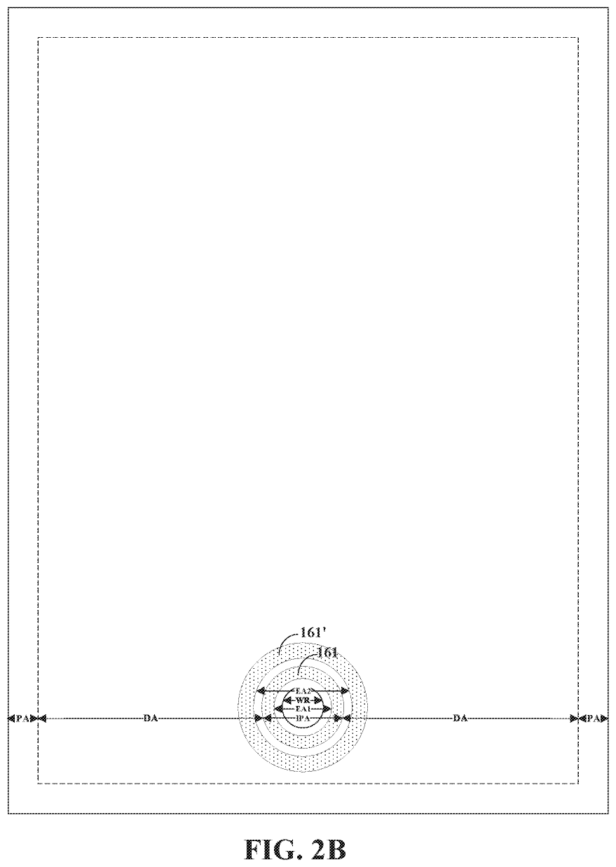

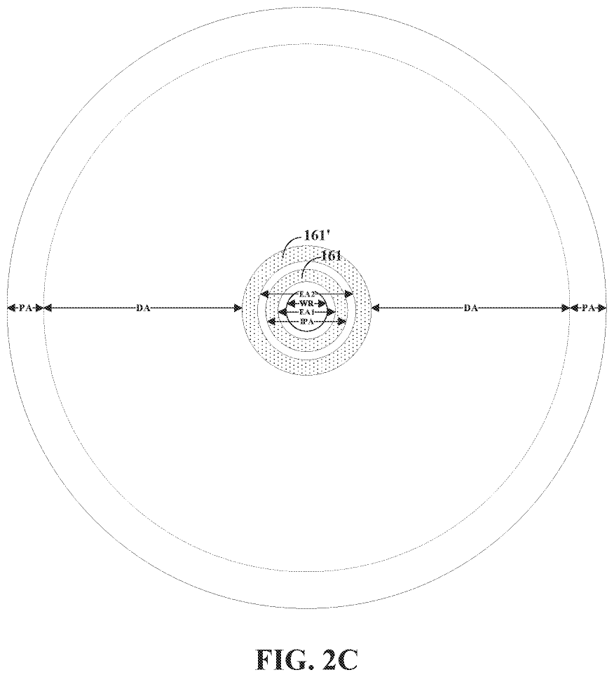

FIG. 2A is a plan view of a display substrate in some embodiments according to the present disclosure. Referring to FIG. 2A, the first enclosure formed by the first barrier wall 161 in the peripheral area PA substantially surrounds a first area EA1. The first enclosure substantially surrounds the display area DA, and the first area EA1 has an area equal to or greater than an area of the display area DA.

FIG. 2B is a plan view of a display substrate in some embodiments according to the present disclosure. Referring to FIG. 2B, the display substrate has a substantially rectangular shape. In some embodiments, the first enclosure formed by the first barrier wall 161 in the peripheral area PA substantially surrounds a first area EA1. The first enclosure does not surround the display area DA, but substantially surrounds an inner peripheral area IPA which is substantially surrounded by the display area DA. The inner peripheral area IPA has an area equal to or greater than an area of the first area EA1. Optionally, the first enclosure substantially surrounds a window region WR of the display substrate, the display substrate has an aperture extending through the window region WR for installing an accessory (e.g., a camera lens, a fingerprint sensor) therein. Optionally, the first area EA1 has an area equal to or greater than an area of the window region WR.

FIG. 2C is a plan view of a display substrate in some embodiments according to the present disclosure. Referring to FIG. 2C, the display substrate has a substantially circular shape. In some embodiments, the first enclosure formed by the first barrier wall in the peripheral area PA substantially surrounds a first area EA1. The first enclosure does not surround the display area DA, but substantially surrounds an inner peripheral area IPA which is substantially surrounded by the display area DA. The inner peripheral area IPA has an area equal to or greater than an area of the first area EA1. Optionally, the first enclosure substantially surrounds a window region WR of the display substrate, the display substrate has an aperture extending through the window region WR for installing an accessory (e.g., a camera lens, a fingerprint sensor) therein. Optionally, the first area EA1 has an area equal to or greater than an area of the window region WR.

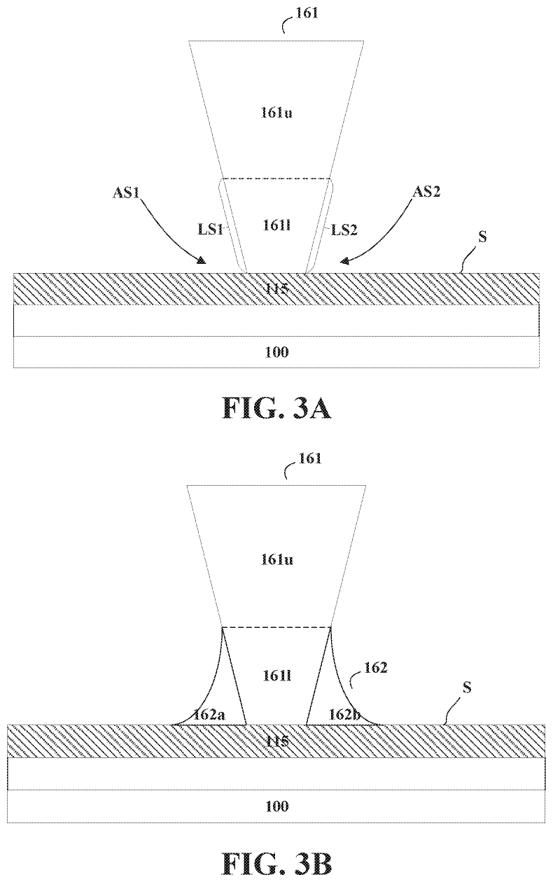

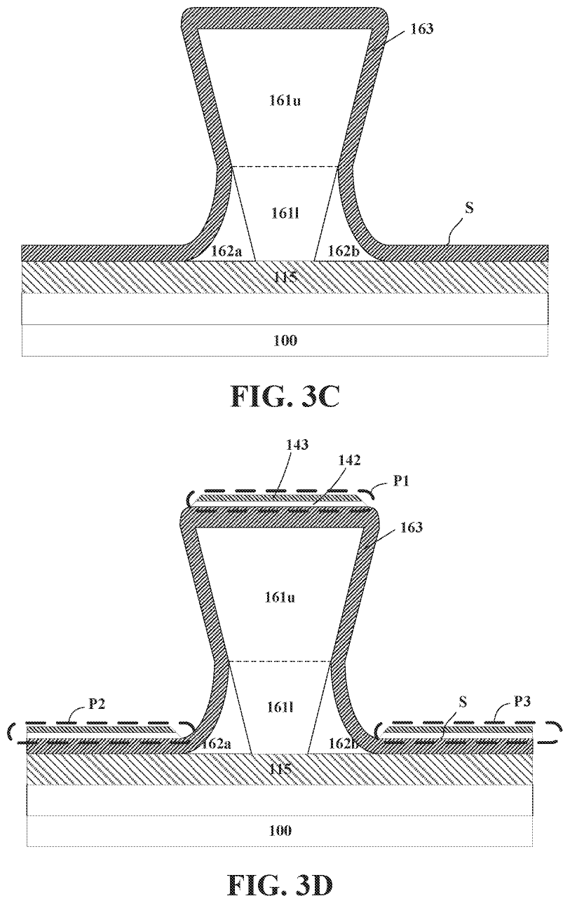

FIG. 3A is a schematic diagram illustrating the structure of a first barrier wall in some embodiments according to the present disclosure. Referring to FIG. 3A, the first barrier wall 161 in some embodiments includes a first lower portion 161l in contact with the insulating layer 115 and a first upper portion 161u on a side of the first lower portion 161l away from the insulating layer 115. An orthographic projection of the first upper portion 161u on the base substrate 100 covers an orthographic projection of the first lower portion 161l on the base substrate 100. Optionally, a width of the first upper portion 161u along a direction from the first lateral side LS1 to the second lateral side LS2 is greater than a width of the first lower portion 161l along the direction from the first lateral side LS1 to the second lateral side LS2. Optionally, a minimum width of the first upper portion 161u along the direction from the first lateral side LS1 to the second lateral side LS2 is equal to or greater than a maximum width of the first lower portion 161l along the direction from the first lateral side LS1 to the second lateral side LS2. Optionally, a side (e.g., a top side) of the first upper portion 161u away from the base substrate 100 is wider than a side (e.g., a bottom side) of the first upper portion 161u closer to the base substrate 100. Optionally, a side (e.g., a top side) of the first lower portion 161l away from the base substrate 100 is wider than a side (e.g., a bottom side) of the first lower portion 161l closer to the base substrate 100. Optionally, a cross-section of the first barrier wall 161 along a plane perpendicular to the insulating layer 115 along the direction from the first lateral side LS1 to the second lateral side LS2 has a substantially inverted trapezoidal shape. Optionally, a cross-section of the first upper portion 161u along a plane perpendicular to the insulating layer 115 along the direction from the first lateral side LS1 to the second lateral side LS2 has a substantially inverted trapezoidal shape. Optionally, a cross-section of the first lower portion 161l along a plane perpendicular to the insulating layer 115 along the direction from the first lateral side LS1 to the second lateral side LS2 has a substantially inverted trapezoidal shape.

In some embodiments, a first lateral side LS1 of the first lower portion 161l forms a first angled space AS1 with a surface S of the insulating layer 115; and a second lateral side LS2 of the first lower portion 161l forms a second angled space AS2 with the surface S of the insulating layer 115. As used herein, the term “lateral side” is used in its ordinary sense and refers without limitation to a side connecting a top side and a bottom side, for example, a side connecting a top side of the first lower portion 161l away from the base substrate 100 and a bottom side of the first lower portion 161l closer to the base substrate 100. In one example, the lateral side is a side rising on the sides from a bottom surface.

FIG. 3B is a schematic diagram illustrating the structure of a first barrier wall and a crack prevention layer in some embodiments according to the present disclosure. Referring to FIG. 3A and FIG. 3B, in some embodiments, the crack prevention layer 162 includes a first crack prevention sub-layer 162a in the first angled space AS1 and a second crack prevention sub-layer 162b in the second angled space AS2. The first crack prevention sub-layer 162a covers the first lateral side LS1 of the first lower portion 161l; and the second crack prevention sub-layer 162b covers the second lateral side LS2 of the first lower portion 161l. As shown in FIG. 3B, the first lower portion 161l, the first crack prevention sub-layer 162a, and the second crack prevention sub-layer 162b together forms a structure having a side away from the base substrate narrower than a side closer to the base substrate (e.g., a quasi-trapezoidal shape). Optionally, a height of the first crack prevention sub-layer 162a relative to the surface S of the insulating layer 115 is no more than half of a height of the first barrier wall 161 relative to the surface S of the insulating layer 115; and a height of the second crack prevention sub-layer 162b relative to the surface S of the insulating layer 115 is no more than half of a height of the first barrier wall 161 relative to the surface S of the insulating layer 115. Optionally, the first crack prevention sub-layer 162a has a lateral side having a concave surface. Optionally, the second crack prevention sub-layer 162b has a lateral side having a concave surface. Optionally, the structure formed by first barrier wall 161, the first crack prevention sub-layer 162a, and the second crack prevention sub-layer 162b form a combined wall having two concave wall side.

Optionally, the first crack prevention sub-layer 162a forms an enclosure substantially surrounding an area smaller than the first area substantially surrounded by the first barrier wall 161. Optionally, the second crack prevention sub-layer 162b forms an enclosure substantially surrounding an area greater than the first area substantially surrounded by the first barrier wall 161. Optionally, the enclosure formed by the second crack prevention sub-layer 162b encloses the first enclosure formed by the first barrier wall 161, and the first enclosure encloses the enclosure formed by the first crack prevention sub-layer 162a. Optionally, the crack prevention layer 162 and the first barrier wall 161 are made using different materials.

FIG. 3C is a schematic diagram illustrating the structure of a first barrier wall, a crack prevention layer, and an inorganic blocking layer in some embodiments according to the present disclosure. Referring to FIG. 1 and FIG. 3C, the display substrate in some embodiments further includes an inorganic blocking layer 163 covering the first barrier wall 161 and the crack prevention layer 162. Optionally, the inorganic blocking layer 163 is limited in the peripheral area PA. Optionally, the inorganic blocking layer 163 is in direct contact with both the first barrier wall 161 and the crack prevention layer 162. Optionally, the inorganic blocking layer 163 further extends into regions outside the first barrier wall 161 and the crack prevention layer 162, and is in direct contact with the insulating layer 115.

Specifically, referring to FIGS. 3A to 3C, the inorganic blocking layer 163 covers and optionally is in direct contact with a top surface (e.g., a surface away from the base substrate 100) of the first upper portion 161u. The inorganic blocking layer 163 further covers and optionally is in direct contact with lateral sides of the first upper portion 161u. The inorganic blocking layer 163 further covers and optionally is in direct contact with the lateral side of the first crack prevention sub-layer 162a, and covers and optionally is in direct contact with the lateral side of the second crack prevention sub-layer 162b.

By having the crack prevention layer 162 (including the first crack prevention sub-layer 162a and the second crack prevention sub-layer 162b), the angled space between the lateral side of the first barrier wall 161 and a surface of the insulating layer 115 can be at least partially filled. The crack prevention layer 162 further stabilizes the first barrier wall 161 on the insulating layer 115. By at least partially eliminating the dead space between the lateral side of the first barrier wall 161 and a surface of the insulating layer 115, subsequent inorganic blocking layer 163 can be formed in this region without cracks, thereby completely encapsulating the display area. For example, in some embodiments, the inorganic blocking layer 163 completely covers, without cracks, lateral sides of a structure formed by the first barrier wall 161 and the crack prevention layer 162 together.

FIG. 3D is a schematic diagram illustrating the structure of an organic material layer and a cathode layer on a first barrier wall in some embodiments according to the present disclosure. Referring to FIG. 1 and FIG. 3D, in some embodiments, the display substrate further includes one or a combination of an organic material layer 142 (e.g., an organic light emitting layer) and a cathode layer 143 on a side of the inorganic blocking layer 163 away from the base substrate 100, isolated into discontinued portions by lateral sides of the first barrier wall 161. For example, FIG. 3D shows a first portion P1, a second portion P2, and a third portion P3 that are isolated into discontinued portions by lateral sides of the first barrier wall 161. The first portion P1 is on a side of the first barrier wall 161 away from the base substrate 100, an orthographic projection of the first portion P1 on the base substrate 100 at least partially overlaps with an orthographic projection of the first barrier wall 161 on the base substrate 100. The second portion P2 and the third portion P3 are on a side of the inorganic blocking layer 163 away from the base substrate 100, orthographic projections of the second portion P2 and the third portion P3 on the base substrate 100 are substantially non-overlapping (e.g., completely non-overlapping) with the orthographic projection of the first barrier wall 161 on the base substrate 100. As used herein, the term “substantially non-overlapping” refers to two orthographic projections being at least 50 percent (e.g., at least 60%, at least 70%, at least 80%, at least 90%, at least 95%, at least 99%, and 100%) non-overlapping.

The organic material layer 142 and the cathode layer 143 may be formed in a same process for forming an organic material layer 142 and a cathode layer 143 for the plurality of light emitting elements 140 in the display area DA. For example, in some embodiments, the organic material layer 142 and the cathode layer 143 for the plurality of light emitting elements 140 are respectively formed in an open mask deposition process, in which no mask plate is used and the target material is deposited onto an entire surface of the substrate. By having a first barrier wall 161 that is wider on top and narrower on bottom, the organic material layer 142 and the cathode layer 143 can be isolated into discontinued portions.

Optionally, the organic material layer 142 includes at least one of an organic light emitting layer, a hole transport layer, a hole injection layer, an electron transport layer, an electron injection layer, or any other organic functional layer in the plurality of light emitting element 140. Optionally, the organic material layer 142 includes at least one of an electron transport layer or an electron injection layer, but does not include an organic light emitting layer (which is not formed in an open mask process).

Referring to FIG. 1, in some embodiments, the encapsulating layer 150 includes a first inorganic encapsulating sub-layer 151, an organic encapsulating sub-layer 152, and a second inorganic encapsulating sub-layer 153. In some embodiments, at least one inorganic sub-layer of the encapsulating layer 150 extends from the display area DA into the peripheral area PA. In one example, the first inorganic encapsulating sub-layer 151 and the second inorganic encapsulating sub-layer 153 extend from the display area DA into the peripheral area PA. Optionally, each of the first inorganic encapsulating sub-layer 151, the organic encapsulating sub-layer 152, and the second inorganic encapsulating sub-layer 153 extends from the display area DA into the peripheral area PA. Optionally, the at least one inorganic sub-layer of the encapsulating layer 150 is on a side of the inorganic blocking layer 163 away from the base substrate 100. Optionally, the at least one inorganic sub-layer of the encapsulating layer 150 is on a side of the first barrier wall 161 away from the base substrate 100.

In one example, the at least one inorganic sub-layer of the encapsulating layer 150 (e.g., one or both of the first inorganic encapsulating sub-layer 151 and the second inorganic encapsulating sub-layer 153) completely covers, without cracks, a portion of the inorganic blocking layer 163 covering the lateral sides of the structure formed by the first barrier wall and the crack prevention layer together. By having the crack prevention layer 162 (including the first crack prevention sub-layer 162a and the second crack prevention sub-layer 162b), the angled space between the lateral side of the first barrier wall 161 and a surface of the insulating layer 115 can be at least partially filled. The crack prevention layer 162 further stabilizes the first barrier wall 161 on the insulating layer 115. By at least partially eliminating the dead space between the lateral side of the first barrier wall 161 and a surface of the insulating layer 115, subsequent inorganic sub-layer of the encapsulating layer 150 can be formed in this region without cracks, thereby completely encapsulating the display area. For example, in some embodiments, the at least one inorganic sub-layer of the encapsulating layer 150 completely covers, without cracks, lateral sides of a structure formed by the first barrier wall 161 and the crack prevention layer 162 together.

The display substrate in some embodiments may include any appropriate numbers of barrier walls, each forming an enclosure substantially surrounding an area (e.g., a window region or a display area as discussed in FIG. 2A and FIG. 2B). Optionally, the display substrate may include a total number of 1-20 barrier walls. In some embodiments, as shown in FIG. 1, FIG. 2A, and FIG. 2B, the display substrate further includes a second barrier wall 161′ in the peripheral area PA and on a side of the insulating layer 115 away from the base substrate 100. The second barrier wall 161′ forms a second enclosure substantially surrounding a second area EA2. Optionally, the second area EA2 encloses the first area EA1.

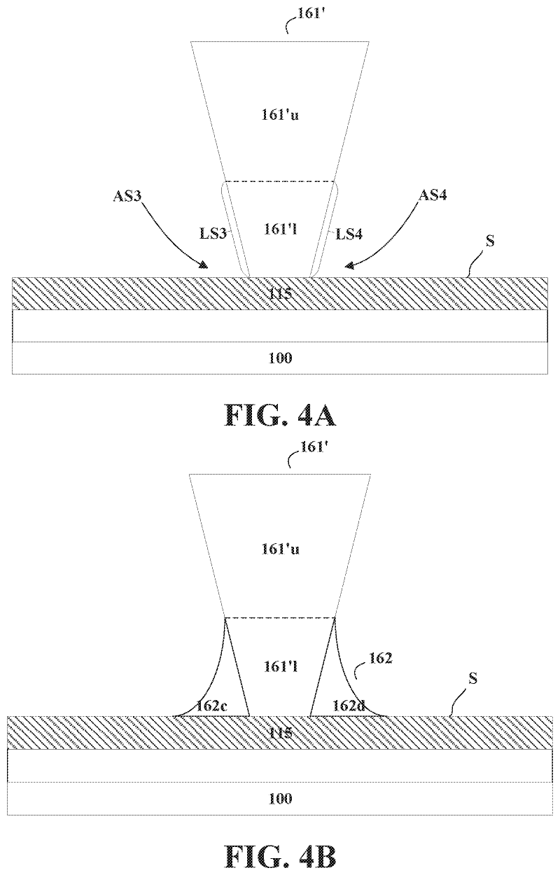

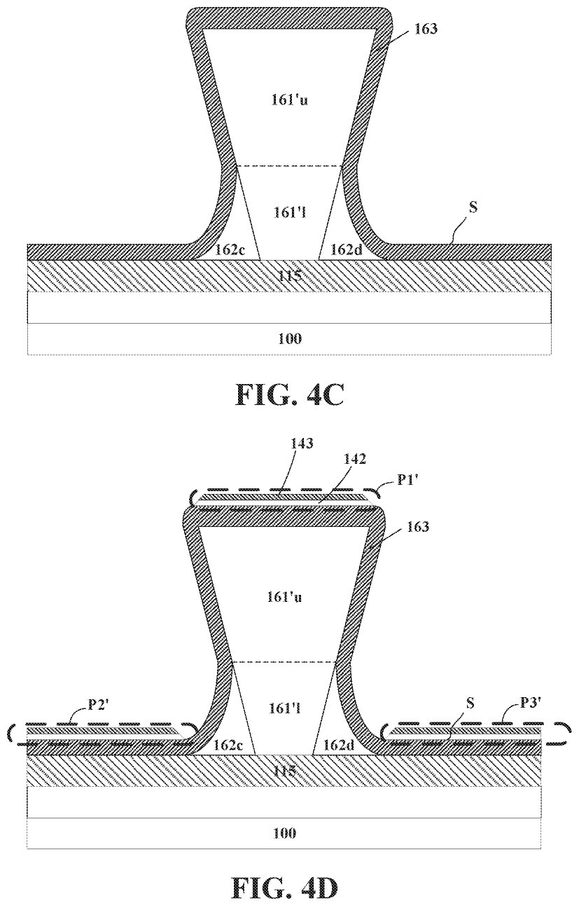

The second barrier wall 161′ in some embodiments has a structure similar to that of the first barrier wall 161. FIG. 4A is a schematic diagram illustrating the structure of a second barrier wall in sonic embodiments according to the present disclosure. FIG. 4B is a schematic diagram illustrating the structure of a second barrier wall and a crack prevention layer in some embodiments according to the present disclosure. FIG. 4C is a schematic diagram illustrating the structure of a second barrier wall, a crack prevention layer, and an inorganic blocking layer in some embodiments according to the present disclosure. FIG. 4D is a schematic diagram illustrating the structure of an organic material layer and a cathode layer on a second barrier wall in sonic embodiments according to the present disclosure. Referring to FIGS. 1, 4B to 4D, the crack prevention layer 162 is in an angled space between a lateral side of the second barrier wall 161′ and a surface S of the insulating layer 115. In some embodiments, the second barrier wall 161′ includes a second lower portion 161′l in contact with the insulating layer 115 and a second upper portion 161′u on a side of the second lower portion 161′l away from the insulating layer 115. Optionally, an orthographic projection of the second upper portion 161′u on the base substrate 100 covers an orthographic projection of the second lower portion 161′l on the base substrate 100. Optionally, a third lateral side LS3 of the second lower portion 161′l forms a third angled space AS3 with a surface S of the insulating layer 115, and a fourth lateral side LS4 of the second lower portion 161′l forms a fourth angled space AS4 with the surface S of the insulating layer 115. Optionally, the crack prevention layer 162 includes a third crack prevention sub-layer 162c in the third angled space AS3 and a fourth crack prevention sub-layer 162d in the fourth angled space AS4. Optionally, the third crack prevention sub-layer 162c covers the third lateral side LS3 of the second lower portion 161′l; and the fourth crack prevention sub-layer 162d covers the fourth lateral side LS4 of the second lower portion 161′l.

In some embodiments, a side of the second upper portion 161′u away from the base substrate 100 is wider than a side of the second upper portion 161′u closer to the base substrate 100; and a side of the second lower portion 161′l away from the base substrate 100 is wider than a side of the second lower portion 161′l closer to the base substrate 100. Optionally, a cross-section of the second barrier wall 161′ along a plane perpendicular to the insulating layer 115 along a direction from the third lateral side LS3 to the fourth lateral side LS4 has a substantially inverted trapezoidal shape. Optionally, the second lower portion 161′l, the third crack prevention sub-layer 162c, and the fourth crack prevention sub-layer 162d together forms a structure having a side away from the base substrate 100 narrower than a side closer to the base substrate 100. Optionally, a height of the third crack prevention sub-layer 162c relative to the surface S of the insulating layer 115 is no more than half of a height of the second barrier wall 161′ relative to the surface S of the insulating layer 115; and a height of the fourth crack prevention sub-layer 162d relative to the surface S of the insulating layer 115 is no more than half of a height of the second barrier wall 161′ relative to the surface S of the insulating layer 115. Optionally, the first barrier wall 161 and the second barrier wall 161′ include a negative photoresist material; and the crack prevention layer 162 includes a positive photoresist material. Optionally, the structure formed by second barrier wall 161′, the third crack prevention sub-layer 162c, and the fourth crack prevention sub-layer 162d form a combined wall having two concave wall side.

In some embodiments, the inorganic blocking layer 163 substantially covers the first barrier wall 161, the crack prevention layer 162, the second barrier wall 161′, and any region between the first barrier wall 161 and the second barrier wall 161′. The inorganic blocking layer 163 is limited in the peripheral area PA. Optionally, the inorganic blocking layer 163 is in direct contact with the first barrier wall 161, the crack prevention layer 162, the second barrier wall 161′, and the insulating layer 115. Optionally, the inorganic blocking layer 163 completely covers, without cracks, lateral sides of a structure formed by the second barrier wall 161′, the third crack prevention sub-layer 162c, and the fourth crack prevention sub-layer 162d together.

In some embodiments, one or a combination of the organic material layer 142 and the cathode layer 143 are on a side of the inorganic blocking layer away from the base substrate, isolated into discontinued portions by lateral sides of the second barrier wall 161′. For example, FIG. 4D shows a fourth portion P1′, a fifth portion P2′, and a sixth portion P3′ that are isolated into discontinued portions by lateral sides of the second barrier wall 161′. The fourth portion P1′ is on a side of the second barrier wall 161′ away from the base substrate 100, an orthographic projection of the fourth portion P1′ on the base substrate 100 at least partially overlaps with an orthographic projection of the second barrier wall 161′ on the base substrate 100. The fifth portion P2′and the sixth portion P3′ are on a side of the inorganic blocking layer 163 away from the base substrate 100, orthographic projections of the fifth portion P2′and the sixth portion P3′ on the base substrate 100 are substantially non-overlapping (e.g., completely non-overlapping) with the orthographic projection of the second barrier wall 161′ on the base substrate 100.

In some embodiments, at least one inorganic sub-layer of the encapsulating layer 150 (e.g., one or both of the first inorganic encapsulating sub-layer 151 and the second inorganic encapsulating sub-layer 153) is on a side of the inorganic blocking layer 163 away from the base substrate 100. Optionally, the at least one inorganic sub-layer of the encapsulating layer 150 is on a side of the second barrier wall 161′ away from the base substrate 100. Optionally, the at least one inorganic sub-layer of the encapsulating layer 150 (e.g., one or both of the first inorganic encapsulating sub-layer 151 and the second inorganic encapsulating sub-layer 153) completely covers, without cracks, a portion of the inorganic blocking layer 163 covering the lateral sides of the structure formed by the second barrier wall 161′, the third crack prevention sub-layer 162c, and the fourth crack prevention sub-layer 162d together. By having the crack prevention layer 162 (including the third crack prevention sub-layer 162c and the fourth crack prevention sub-layer 162d), the angled space between the lateral side of the second barrier wall 161′ and a surface of the insulating layer 115 can be at least partially filled. The crack prevention layer 162 further stabilizes the second barrier wall 161′ on the insulating layer 115. By at least partially eliminating the dead space between the lateral side of the second barrier wall 161′ and a surface of the insulating layer 115, subsequent inorganic sub-layer of the encapsulating layer 150 can be formed in this region without cracks, thereby completely encapsulating the display area. For example, in some embodiments, the at least one inorganic sub-layer of the encapsulating layer 150 completely covers, without cracks, lateral sides of a structure formed by the second barrier wall 161′, the third crack prevention sub-layer 162c, and the fourth crack prevention sub-layer 162d together.

Optionally, each of the first enclosure and the second enclosure substantially surrounds a window region of the display substrate, and the display substrate has an aperture extending through the window region for installing an accessory therein. Examples of accessories that may be installed in the window region include an earpiece, a camera, a photosensor, a distance sensor, an infrared sensor, a fingerprint sensor, an acoustic sensor, an indicator, a button, a knob, or any combination thereof.

In some embodiments, each of the first barrier wall 161 and the second barrier wall 161′ has a thickness in a range of 0.5 μm to 5 μm. Optionally, each of the first barrier wall 161 and the second barrier wall 161′ has a width in a range of 2 μm to 100 μm.

Various appropriate materials and various appropriate fabricating methods may be used to make the first barrier wall 161 and the second barrier wall 161′. For example, an insulating material may be deposited by a plasma-enhanced chemical vapor deposition (PECVD) process or a sputtering process, e.g., a magnetron sputtering process. The deposited insulating material layer is then patterned, e.g., by a lithographic process. Optionally, each of the first barrier wall 161 and the second barrier wall 161′ is made of a negative photoresist material. The first barrier wall 161 and the second barrier wall 161′ may he formed by forming a negative photoresist material layer in the peripheral area and on a side of the insulating layer away from the base substrate; and patterning the negative photoresist material layer to form the first barrier wall and the second barrier wall. Due to the property of the negative photoresist material, exposure and development of the negative photoresist material results in an undercut profile of the first barrier wall 161 or the second barrier wall 161′, e.g., a side of the first barrier wall 161 or the second barrier wall 161′ away from the base substrate 100 is wider than a side of the first barrier wall 161 or the second barrier wall 161′ closer to the base substrate 100.

Various appropriate materials and various appropriate fabricating methods may be used to make the crack prevention layer 162. For example, an insulating material may be deposited by a plasma-enhanced chemical vapor deposition (PECVD) process or a sputtering process, e.g., a magnetron sputtering process. The deposited insulating material layer is then patterned, e.g., by a lithographic process. Optionally, the crack prevention layer 162 is made of a positive photoresist material. The crack prevention layer 162 may be formed by forming a positive photoresist material layer on a side of the first barrier wall away from the base substrate; and patterning the positive photoresist material layer to form the crack prevention layer. The positive photoresist material layer is formed to he filled in the angled space. Due to the undercut profile of the first barrier wall 161, the positive photoresist material filled in the angled space is not exposed or insufficiently exposed. During development of the positive photoresist material layer, the positive photoresist material in the angled space remains, whereas the positive photoresist material layer is removed during the patterning the positive photoresist material layer, except for a portion in the angled space between the lateral side of the first barrier wall 161 and the surface S of the insulating layer 115, thereby forming the crack prevention layer 162.

In some embodiments, the inorganic blocking layer 163 has a thickness in a range of 10 nm to 3 μm. Various appropriate materials and various appropriate fabricating methods may be used to make the inorganic blocking layer 163. For example, an insulating material may be deposited by a plasma-enhanced chemical vapor deposition (PECVD) process or a sputtering process, e.g., a magnetron sputtering process. The deposited insulating material layer is then patterned, e.g., by a lithographic process. Examples of appropriate insulating material for making the inorganic blocking layer 163 include silicon oxide, silicon nitride, silicon oxynitride, aluminum oxide, and any combination thereof.

Referring to FIG. 1, in some embodiments, the display substrate further includes a barrier layer 101 on the base substrate 100, and a plurality of thin film transistors in the display area DA and on a side of the barrier layer away from the base substrate 100. A respective one of the plurality of thin film transistors includes an active layer 110 on the barrier layer 101, a first gate insulating layer 111 on a side of the active layer 110 away from the base substrate 100, a gate electrode 112 on a side of the first gate insulating layer 111 away from the base substrate 100, the insulating layer 115 on a side of the gate electrode 112 away from the base substrate 100, a source electrode 121 and a drain electrode 122 on a side of the insulating layer 115 away from the base substrate 100. Optionally, the display substrate further includes a second gate insulating layer 113 between the first gate insulating layer 111 and the insulating layer 115. Optionally, the display substrate further includes a first electrode 112′ and a second electrode 114. The second gate insulating layer 113 spaces apart the first electrode 112′ and a second electrode 114 from each other. The first electrode 112′, the second gate insulating layer 113, and a second electrode 114 form a capacitor.

A respective one of the plurality of light emitting elements 140 includes an anode 132, a light emitting layer 141 on the anode 132, the organic material layer 142 on a side of the light emitting layer 141 away from the base substrate 100, the cathode layer 143 on a side of the organic material layer 142 away from the base substrate 100. Optionally, the organic material layer 142 and the cathode layer 143 can be formed in an open mask process.

In some embodiments, the display substrate further includes a planarization layer 131 on a side of the plurality of thin film transistors away from the base substrate 100. The anode 132 is electrically connected to the drain electrode 122 of the respective one of the plurality of thin film transistor through a via extending through the planarization layer 131.

In some embodiments, the display substrate further includes a pixel definition layer 133 on a side of the planarization layer 131 away from the base substrate 100. The pixel definition layer 133 defines a plurality of subpixel apertures for receiving the light emitting layer 141.

In some embodiments, the display substrate further includes a spacer 134 on the pixel definition layer 133.

Optionally, the crack prevention layer 162 and the planarization layer 131 are formed in a same patterning process using a same mask plate, the crack prevention layer 162 and the planarization layer 131 are formed in a same layer and using a same insulating material. As used herein, the term “same layer” refers to the relationship between the layers simultaneously formed in the same step. In one example, the crack prevention layer 162 and the planarization layer 131 are in a same layer when they are formed as a result of one or more steps of a same patterning process performed in a same layer of material. In another example, the crack prevention layer 162 and the planarization layer 131 can be formed in a same layer by simultaneously performing the step of forming the crack prevention layer 162 and the step of forming the planarization layer 131. The term “same layer” does not always mean that the thickness of the layer or the height of the layer in a cross-sectional view is the same.

Optionally, the crack prevention layer 162 and the pixel definition layer 133 are formed in a same patterning process using a same mask plate, the crack prevention layer 162 and the pixel definition layer 133 are formed in a same layer and using a same insulating material.

Optionally, the crack prevention layer 162 and the spacer 134 are formed in a same patterning process using a same mask plate, the crack prevention layer 162 and the spacer 134 are formed in a same layer and using a same insulating material.

In another aspect, the present disclosure provides a method of fabricating a display substrate having a display area and a peripheral area. In some embodiments, the method includes forming a plurality of light emitting elements on a base substrate and in the display area; forming an encapsulating layer on a side of the plurality of light emitting elements distal to the base substrate to encapsulate the plurality of light emitting elements; forming an insulating layer on the base substrate; forming a first barrier wall in the peripheral area and on a side of the insulating layer away from the base substrate, the first barrier wall forming a first enclosure substantially surrounding a first area; and forming a crack prevention layer in an angled space between a lateral side of the first barrier wall and a surface of the insulating layer.

In some embodiments, forming the first barrier wall includes forming a negative photoresist material layer in the peripheral area and on a side of the insulating layer away from the base substrate; and patterning the negative photoresist material layer to form the first barrier wall. Optionally, the first barrier wall is formed so that a side of the first barrier wall away from the base substrate is wider than a side of the first barrier wall closer to the base substrate.

In some embodiments, forming the crack prevention layer includes forming a positive photoresist material layer on a side of the first barrier wall away from the base substrate; and patterning the positive photoresist material layer to form the crack prevention layer. Optionally, the positive photoresist material layer is removed during the patterning the positive photoresist material layer, except for a portion in the angled space between the lateral side of the first barrier wall and the surface of the insulating layer, thereby forming the crack prevention layer.

In some embodiments, the method further includes punching an aperture through the display substrate to form a window region. Optionally, window region is substantially surrounded by the first enclosure. Optionally, parching the aperture is performed by any one or any combination of a mechanical process, a laser, or an etching process. The step of punching an aperture is performed subsequent to forming an encapsulating layer.

In some embodiments, the first barrier wall is formed to include a first lower portion in contact with the insulating layer and a first upper portion on a side of the first lower portion away from the insulating layer. A lateral side of the first lower portion is formed to be covered by the crack prevention layer, and a lateral side of the first upper portion is formed to be absent of the crack prevention layer. An orthographic projection of the first upper portion on the base substrate covers an orthographic projection of the first lower portion on the base substrate. A first lateral side of the first lower portion forms a first angled space with a surface of the insulating layer. A second lateral side of the first lower portion forms a second angled space with the surface of the insulating layer.

In some embodiments, the first barrier wall is formed so that a side of the first upper portion away from the base substrate is wider than a side of the first upper portion closer to the base substrate; and a side of the first lower portion away from the base substrate is wider than a side of the first lower portion closer to the base substrate. Optionally, a cross-section of the first barrier wall along a plane perpendicular to the insulating layer along a direction from the first lateral side to the second lateral side has a substantially inverted trapezoidal shape.

In some embodiments, the crack prevention layer is formed to include a first crack prevention sub-layer in the first angled space and a second crack prevention sub-layer in the second angled space. Optionally, the first crack prevention sub-layer is formed to cover a first lateral side of the first lower portion. Optionally, the second crack prevention sub-layer is formed to cover the second lateral side of the first lower portion. Optionally, the first lower portion, the first crack prevention sub-layer, and the second crack prevention sub-layer are formed to collectively constitute a structure having a side away from the base substrate narrower than a side closer to the base substrate. Optionally, the crack prevention layer is formed so that a height of the first crack prevention sub-layer relative to the surface of the insulating layer is no more than half of a height of the first barrier wall relative to the surface of the insulating layer, and a height of the second crack prevention sub-layer relative to the surface of the insulating layer is no more than half of a height of the first barrier wall relative to the surface of the insulating layer.

In some embodiments, the method further includes forming an inorganic blocking layer covering the first barrier wall and the crack prevention layer. The inorganic blocking layer is limited in the peripheral area. Optionally, the inorganic blocking layer is formed to be in direct contact with the first barrier wall, the crack prevention layer, and the insulating layer. Optionally, the inorganic blocking layer is formed to completely cover, without cracks, lateral sides of a structure formed by the first barrier wall and the crack prevention layer together.

In some embodiments, the method further includes forming one or a combination of an organic material layer and a cathode layer on a side of the inorganic blocking layer away from the base substrate, isolated into discontinued portions by lateral sides of the first barrier wall.

In some embodiments, the method further includes forming an encapsulating layer to encapsulate the plurality of light emitting elements. Optionally, at least one inorganic sub-layer of the encapsulating layer is formed to extend from the display area into the peripheral area. Optionally, the at least one inorganic sub-layer of the encapsulating layer is formed on a side of the inorganic blocking layer away from the base substrate. Optionally, the at least one inorganic sub-layer of the encapsulating layer is formed to completely cover, without cracks, a portion of the inorganic blocking layer covering the lateral sides of the structure formed by the first barrier wall and the crack prevention layer together.

In some embodiments, the method further includes forming a second barrier wall in the peripheral area and on a side of the insulating layer away from the base substrate, the second barrier wall forming a second enclosure substantially surrounding a second area.

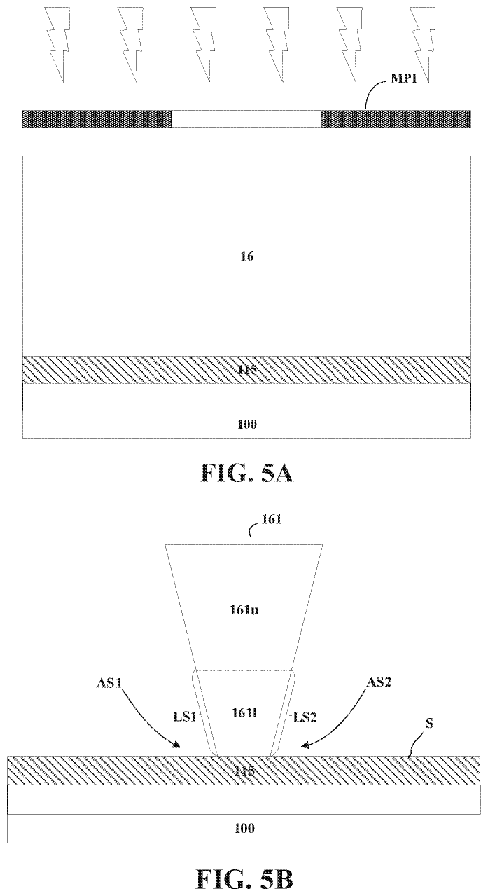

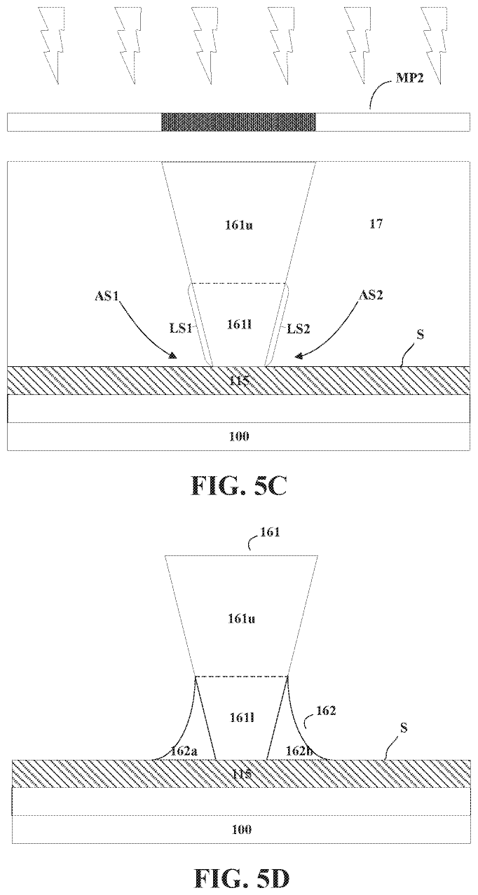

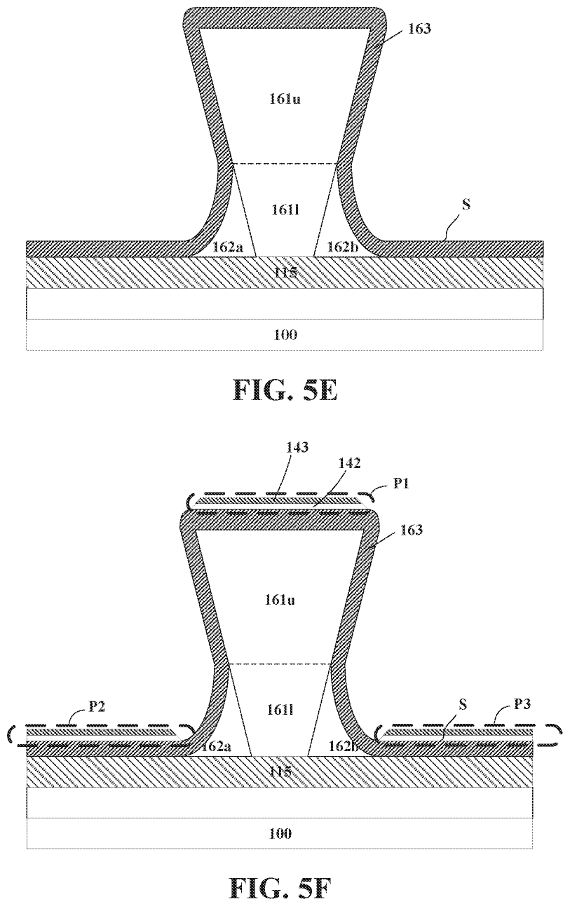

FIGS. 5A to 5F illustrate a method of fabricating a display substrate in some embodiments according to the present disclosure. Referring to FIG. 5A, a negative photoresist material layer 16 is formed on the insulating layer 115, the negative photoresist material layer 16 is exposed using a first mask plate MP1, the region of the first mask plate MP1 corresponding to the first barrier wall 161 is light transmissive, and the region of the first mask plate MP1 corresponding to portions outside the first barrier wall 161 is light blocking. The exposed negative photoresist material layer 16 is then developed.

Referring to FIG. 5B, due to the property of the negative photoresist material, exposure and development of the negative photoresist material layer 16 results in an undercut profile of the first barrier wall 161, e.g., a side of the first barrier wall 161 away from the base substrate 100 is wider than a side of the first barrier wall 161 closer to the base substrate 100.

Referring to FIG. 5C, a positive photoresist material layer 17 is then formed on the display substrate. The positive photoresist material layer 17 is exposed using a second mask plate MP2, the region of the second mask plate MP2 corresponding to the first barrier wall 161 is light blocking, and the region of the second mask plate MP2 corresponding to portions outside the first barrier wall 161 is light transmissive. The exposed positive photoresist material layer 17 is then developed.

Referring to FIG. 5D, the positive photoresist material is removed except for those in the first angled space AS1 and the second angled spaced AS2 because the positive photoresist material in these spaces are not exposed to light. A crack prevention layer 162 including a first crack prevention sub-layer 162a in the first angled space AS1 and a second crack prevention sub-layer 162b in the second angled spaced AS2 is formed.

Referring to FIG. 5E, an inorganic blocking layer 163 is formed to cover the first barrier wall 161 and the crack prevention layer 162. The inorganic blocking layer 163 is formed to be in direct contact with the first barrier wall 161, the crack prevention layer 162, and the insulating layer 115. The inorganic blocking layer 163 completely covers, without cracks, lateral sides of a structure formed by the first barrier wall 161 and the crack prevention layer 162 together.

Referring to FIG. 5F, during an open mask process, one or a combination of an organic material layer 142 and a cathode layer 143 is deposited on the base substrate 100. In the peripheral area, the organic material layer 142 and the cathode layer 143 are formed on a side of the inorganic blocking layer 163 away from the base substrate 100, isolated into discontinued portions (P1, P2, and P3) by lateral sides of the first barrier wall 161.

Referring to FIG. 1, an encapsulating layer 150 is formed on the display substrate. The first inorganic encapsulating sub-layer 151 and the second inorganic encapsulating sub-layer 153 are formed to extend from the display area DA into the peripheral area PA. In the peripheral area PA, the first inorganic encapsulating sub-layer 151 and the second inorganic encapsulating sub-layer 153 are formed on a side of the inorganic blocking layer 163 away from the base substrate 100.

In another aspect, the present disclosure provides a display apparatus including a display substrate described herein or fabricated by a method described herein, and one or more integrated circuits connected to the display substrate. Optionally, the display apparatus includes a display panel. Optionally, the display panel includes the display substrate described herein or fabricated by a method described herein, and a counter substrate. Examples of appropriate display apparatuses include, but are not limited to, an electronic paper, a mobile phone, a tablet computer, a television, a monitor, a notebook computer, a digital album, a GPS, etc. Optionally, the display apparatus further includes one or more integrated circuits connected to the display panel.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. A display substrate having a display area and a peripheral area, comprising:
a base substrate;
a plurality of light emitting elements on the base substrate and in the display area;
an encapsulating layer on a side of the plurality of light emitting elements distal to the base substrate to encapsulate the plurality of light emitting elements;
an insulating layer between the encapsulating layer and the base substrate;
a first barrier wall in the peripheral area and on a side of the insulating layer away from the base substrate, the first barrier wall forming a first enclosure substantially surrounding a first area; and
a crack prevention layer in an angled space between a lateral side of the first barrier wall and a surface of the insulating layer.

2. The display substrate of claim 1, wherein the first barrier wall comprises a first lower portion in contact with the insulating layer and a first upper portion on a side of the first lower portion away from the insulating layer;
an orthographic projection of the first upper portion on the base substrate covers an orthographic projection of the first lower portion on the base substrate;
a first lateral side of the first lower portion forms a first angled space with a surface of the insulating layer;
a second lateral side of the first lower portion forms a second angled space with the surface of the insulating layer; and
the crack prevention layer comprises a first crack prevention sub-layer in the first angled space and a second crack prevention sub-layer in the second angled space.

3. The display substrate of claim 2, wherein the first crack prevention sub-layer covers the first lateral side of the first lower portion; and
the second crack prevention sub-layer covers the second lateral side of the first lower portion.

4. The display substrate of claim 2, wherein a side of the first upper portion away from the base substrate is wider than a side of the first upper portion closer to the base substrate; and
a side of the first lower portion away from the base substrate is wider than a side of the first lower portion closer to the base substrate.

5. The display substrate of claim 4, wherein a cross-section of the first barrier wall along a plane perpendicular to the insulating layer along a direction from the first lateral side to the second lateral side has a substantially inverted trapezoidal shape.

6. The display substrate of claim 4, wherein the first lower portion, the first crack prevention sub-layer, and the second crack prevention sub-layer together forms a structure having a side away from the base substrate narrower than a side closer to the base substrate.

7. The display substrate of claim 2, wherein a height of the first crack prevention sub-layer relative to the surface of the insulating layer is no more than half of a height of the first barrier wall relative to the surface of the insulating layer; and
a height of the second crack prevention sub-layer relative to the surface of the insulating layer is no more than half of a height of the first barrier wall relative to the surface of the insulating layer.

8. The display substrate of claim 1, wherein the first barrier wall comprises a negative photoresist material; and
the crack prevention layer comprises a positive photoresist material.

9. The display substrate of claim 1, further comprising an inorganic blocking layer covering the first barrier wall and the crack prevention layer;
the inorganic blocking layer is limited in the peripheral area; and
the inorganic blocking layer is in direct contact with the first barrier wall, the crack prevention layer, and the insulating layer.

10. The display substrate of claim 9, wherein the inorganic blocking layer completely covers, without cracks, lateral sides of a structure formed by the first barrier wall and the crack prevention layer together.

11. The display substrate of claim 9, further comprising one or a combination of an organic material layer and a cathode layer on a side of the inorganic blocking layer away from the base substrate, isolated into discontinued portions by lateral sides of the first barrier wall.

12. The display substrate of claim 9, wherein at least one inorganic sub-layer of the encapsulating layer extends from the display area into the peripheral area; and
the at least one inorganic sub-layer of the encapsulating layer is on a side of the inorganic blocking layer away from the base substrate.

13. The display substrate of claim 12, wherein the at least one inorganic sub-layer of the encapsulating layer completely covers, without cracks, a portion of the inorganic blocking layer covering the lateral sides of a structure formed by the first barrier wall and the crack prevention layer together.

14. The display substrate of claim 1, further comprising a second barrier wall in the peripheral area and on a side of the insulating layer away from the base substrate, the second barrier wall forming a second enclosure substantially surrounding a second area.

15. The display substrate of claim 1, wherein the first enclosure substantially surrounds a window region of the display substrate; and
the display substrate has an aperture extending through the window region for installing an accessory therein.

16. A display apparatus, comprising the display substrate of claim 1, and one or more integrated circuits connected to the display substrate.

17. A method of fabricating a display substrate having a display area and a peripheral area, comprising:
forming a plurality of light emitting elements on a base substrate and in the display area;
forming an encapsulating layer on a side of the plurality of light emitting elements distal to the base substrate to encapsulate the plurality of light emitting elements;
forming an insulating layer on the base substrate, wherein the insulating layer is formed between the encapsulating layer and the base substrate;
forming a first barrier wall in the peripheral area and on a side of the insulating layer away from the base substrate, the first barrier wall forming a first enclosure substantially surrounding a first area; and
forming a crack prevention layer in an angled space between a lateral side of the first barrier wall and a surface of the insulating layer.

18. The method of claim 17, wherein forming the first barrier wall comprises:
forming a negative photoresist material layer in the peripheral area and on a side of the insulating layer away from the base substrate; and
patterning the negative photoresist material layer to form the first barrier wall;
wherein the first barrier wall is formed so that a side of the first barrier wall away from the base substrate is wider than a side of the first barrier wall closer to the base substrate.

19. The method of claim 17, wherein forming the crack prevention layer comprises:
forming a positive photoresist material layer on a side of the first barrier wall away from the base substrate; and
patterning the positive photoresist material layer to form the crack prevention layer;
wherein the positive photoresist material layer is removed during the patterning the positive photoresist material layer, except for a portion in the angled space between the lateral side of the first barrier wall and the surface of the insulating layer, thereby forming the crack prevention layer.

20. The method of claim 17, further comprising punching an aperture through the display substrate to form a window region;
wherein the window region is substantially surrounded by the first enclosure.
